(19) United States
(12) Patent Application Publication
(10) Pub. No.: US 2025/0280568 A1
(43) Pub. Date: Sep. 4, 2025

(54) TRANSISTOR AND DISPLAY APPARATUS INCLUDING THE SAME

(71) Applicant: LG Display Co., Ltd., Seoul (KR)

(72) Inventor: Sungju CHOI, Paju-si (KR)

(73) Assignee: LG Display Co., Ltd., Seoul (KR)

(21) Appl. No.: 19/061,748

(22) Filed: Feb. 24, 2025

(30) Foreign Application Priority Data
Feb. 29, 2024 (KR) 10-2024-0030013

(51) Int. Cl. H10D 30/67; H10D 86/40; H10D 86/60; H10K 59/121

(52) U.S. Cl. CPC H10D 30/6736; H10D 30/6732; H10D 30/6755; H10D 30/6757; H10D 86/423; H10D 86/451; H10D 86/60; H10K 59/1213

(57) ABSTRACT

A transistor and a display apparatus including the transistor are discussed. The transistor can include a substrate, a gate electrode disposed on the substrate, a first insulating layer disposed on the gate electrode, and a semiconductor layer disposed on the first insulating layer so as to overlap the gate electrode in a vertical direction. An upper surface of the first insulating layer includes at least one step.

### CROSS-REFERENCE TO RELATED APPLICATION

This application claims priority to Korean Patent Application No. 10-2024-0030013, filed in the Republic of Korea on Feb. 29, 2024, the entire contents of which are hereby expressly incorporated by reference into the present application.

### BACKGROUND

### Field

The present disclosure relates to a transistor and a display apparatus including the transistor.

### Discussion of Related Art

Display apparatuses are applied to various electronic devices such as TVs (televisions), smartphones, laptops, and tablets. To this end, research is being conducted to develop smaller, lighter, and lower power consuming display devices.

Examples of the display apparatus include a liquid crystal display apparatus (LCD), a field emission display apparatus (FED), and an organic light emitting display apparatus (OLED), but other examples are possible.

A transistor is used as an element that controls each of a plurality of pixels included in a display apparatus. At least one transistor can be included in the display apparatus.

### SUMMARY OF THE DISCLOSURE

A technical purpose according to one or more embodiments of the present disclosure is to provide a transistor including an oxide semiconductor capable of implementing high performance and high integration density as a material of a semiconductor layer thereof, and is to provide a display apparatus including such transistor.

Furthermore, a technical purpose according to one or more embodiments of the present disclosure is to provide a single transistor capable of controlling at least one signal and a display apparatus including such transistor.

Purposes according to aspects of the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display apparatus according to one or more embodiments of the present disclosure includes a transistor.

According to an embodiment of the present disclosure, a transistor can include a substrate; a gate electrode disposed on the substrate; a first insulating layer disposed on the gate electrode; and a semiconductor layer disposed on the first insulating layer so as to overlap the gate electrode in a vertical direction, wherein an upper surface of the first insulating layer includes at least one step, wherein the semiconductor layer is disposed on the upper surface of the first insulating layer having the at least one step in a conformal manner.

According to an embodiment of the present disclosure, a display apparatus can include a light-emitting element, and a transistor connected to the light-emitting element, wherein the transistor can include a substrate; a gate electrode disposed on the substrate; a first insulating layer disposed on the gate electrode; and a semiconductor layer disposed on the first insulating layer so as to overlap the gate electrode in a vertical direction, wherein an upper surface of the first insulating layer includes at least one step, wherein the semiconductor layer is disposed on the upper surface of the first insulating layer having the at least one step in a conformal manner.

According to the transistor of an embodiment of the present disclosure, the first insulating layer has different areas having different thicknesses, such that at least two channel areas can be defined in the semiconductor layer, thereby generating a high amount of current across the same area.

According to an embodiment of the present disclosure, the source electrode and each of the drain electrodes are respectively arranged in the vertical direction, such that two different transistor are formed using one gate electrode, thereby obtaining a high current amount across the same area.

Accordingly, reduction in production energy via process optimization can be obtained by improving the performance of the transistor within the same area.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one or more embodiments of the present disclosure.

FIG. 2 is a cross-sectional view of a transistor according to an embodiment of the present disclosure.

FIG. 3 is a diagram showing signal transmission of a transistor according to an embodiment of the present disclosure.

FIG. 4 to FIG. 10 are diagrams showing a method for manufacturing a transistor according to one or more embodiments of the present disclosure.

FIG. 11 is a cross-sectional view of a transistor according to another embodiment of the present disclosure.

FIG. 12 is a diagram showing signal transmission of a transistor according to another embodiment of the present disclosure.

FIG. 13 is a cross-sectional view of a display apparatus including a transistor according to one or more embodiments of the present disclosure.

FIG. 14 and FIG. 15 are current-voltage graphs according to some embodiments of the present disclosure.

### DETAILED DESCRIPTION OF THE EMBODIMENTS

Advantages and features of the present disclosure, and a method of achieving the advantages and features will become apparent with reference to embodiments described below in detail together with the accompanying drawings. However, the present disclosure is not limited to the embodiments as disclosed under, but can be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when a first element or layer is referred to as being “connected to”, or “coupled to” a second element or layer, the first element can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, regions, layers and/or periods, these elements, components, regions, layers and/or periods should not be limited by these terms. These terms are used to distinguish one element, component, region, layer or section from another element, component, region, layer or section. Thus, a first element, component, region, layer or section as described under could be termed a second element, component, region, layer or section, without departing from the spirit and scope of the present disclosure.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects”, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Description of the Embodiments. Further, the term “can” fully encompasses all the meanings and coverages of the term “may.”

In description of flow of a signal, for example, when a signal is delivered from a node A to a node B, this can include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

Hereinafter, a display apparatus according to various embodiments of the present disclosure is described with reference to the attached drawings. All the components of each display apparatus according to all embodiments of the present disclosure are operatively coupled and configured.

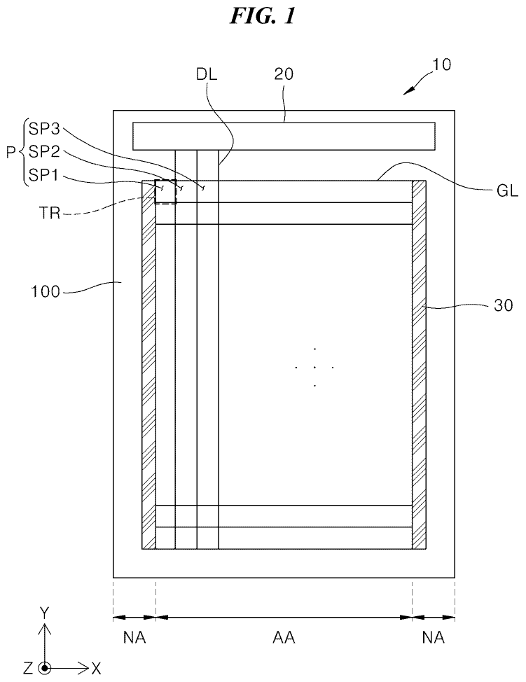

FIG. 1 is a plan view of a display apparatus according to one or more embodiments of the present disclosure.

Referring to FIG. 1, a display apparatus 10 according to one or more embodiments of the present disclosure can include a substrate 100 including a display area AA (or active area) and a non-display area NA (or non-active area) positioned outside the display area AA. The non-display area NA can surround the display area AA entirely or only in part(s).

A plurality of gate lines GL extending in a first direction and a plurality of data lines DL extending in a second direction intersecting the first direction can be disposed on the display area AA of the substrate 100. In each of areas defined by the data lines DL and the gate lines GL intersecting each other, a sub-pixel among a plurality of sub-pixels including sub-pixels SP1, SP2, and SP3 can be disposed. However, embodiments of the present disclosure are not limited thereto.

One gate line GL can extend along the first direction of the substrate 100. The plurality of gate lines SL can be arranged to be spaced apart from each other in the second direction intersecting the first direction. One data line DL can extend along the second direction. The plurality of data lines DL can be arranged to be spaced apart from each other in the first direction intersecting the second direction. The first direction can be, but is not limited to, an X-axis direction or a row direction in a plan view of the substrate 100. The second direction can be, but is not limited to, a Y-axis direction or a column direction in the plan view of the substrate 100.

Each of the different sub-pixels SP1, SP2, and SP3 can have a light-emitting element to emit light of each or one of different colors, such as red, green, and blue light. However, embodiments of the present disclosure are not limited thereto. For example, the sub-pixels SP1, SP2, and SP3 can respectively have light-emitting elements to emit the same color light such as white light, and can respectively emit light beams of different colors to an outside through different color filters.

A pixel P can include a combination of the plurality of sub-pixels SP1, SP2, and SP3. The plurality of sub-pixels SP1, SP2, and SP3 can be arranged in a plurality of rows and columns of the substrate 100 in a matrix form. However, embodiments of the present disclosure are not limited thereto.

Each of the sub-pixels SP1, SP2, and SP3 can include one or more transistors TR. One or more transistors TR can control current or voltage supplied to each of the sub-pixels SP1, SP2, and SP3. Accordingly, the light-emitting element disposed in each of the sub-pixels SP1, SP2, and SP3 can emit light based on the current transmitted thereto through the one or more transistors TR.

A plurality of lines and pads, etc. that supply power or various signals to an inside of the pixel can be disposed in the non-display area NA. The non-display area NA can be positioned around the display area AA.

A driver 20 and 30 can be disposed in the non-display area NA. The driver 20 and 30 can be disposed on at least one side portion of the non-display area NA of the substrate 100. However, embodiments of the present disclosure are not limited thereto.

The driver 20 and 30 can include a gate driver, a data driver, or a timing controller. However, embodiments of the present disclosure are not limited thereto. Furthermore, the display apparatus 10 can include a power line that supplies a power voltage. For example, the data driver 20 can be disposed on one side portion of the non-display area NA, and the gate driver 30 can be disposed on each of both opposing side portions of the non-display area NA. However, embodiments of the present disclosure are not limited thereto.

The data driver 20 can supply a data signal to the data line DL. The gate driver 30 can supply a gate signal to the gate line GL. For example, the gate driver 30 can be disposed on the non-display area NA of the substrate 100. In this case, the gate driver 30 can be implemented in a GIP (Gate diver In Panel) manner. When the gate driver 30 is implemented in the GIP manner, the gate driver can be formed together with transistors or lines and on the display area AA.

One or more transistors TR can be disposed on the display area AA and the non-display area NA of the substrate 100. The transistor TR disposed on the display area AA of the substrate 100 can include a driving transistor, a switching transistor, and a sensing transistor for sensing the light-emitting element disposed in each of the sub-pixels SP1, SP2, and SP3. The transistor TR disposed on the non-display area NA of the substrate 100 can be disposed in the gate driver 30. However, embodiments of the present disclosure are not limited thereto.

As a specification of the display apparatus has an increasingly higher level, it is required that a high current be applied to the transistor that controls each of the sub-pixels SP1, SP2, and SP3.

One of the schemes for applying the high current to the transistor is to include an oxide semiconductor as a material of a semiconductor layer of the transistor. However, when depositing the oxide semiconductor across a large area, a process cost increases, and it is difficult to maintain characteristics of the transistor uniformly.

Accordingly, among the schemes for applying a high-performance oxide semiconductor, there is a scheme of reducing a thickness of an insulating layer positioned under or on top of the semiconductor layer, or changing a material of the insulating layer to change a capacitance ratio, thereby improving the characteristics of the transistor. However, the scheme of reducing the thickness of the insulating layer or changing the material thereof can reduce a driving current Ion. The reduction in the driving current can lead to a reduction in operation efficiency of a compensation circuit. When the operation efficiency of the compensation circuit is reduced, a defect such as a mura in a display panel can occur.

Accordingly, a scheme is needed to increase the driving current Ion while applying the high-performance oxide semiconductor.

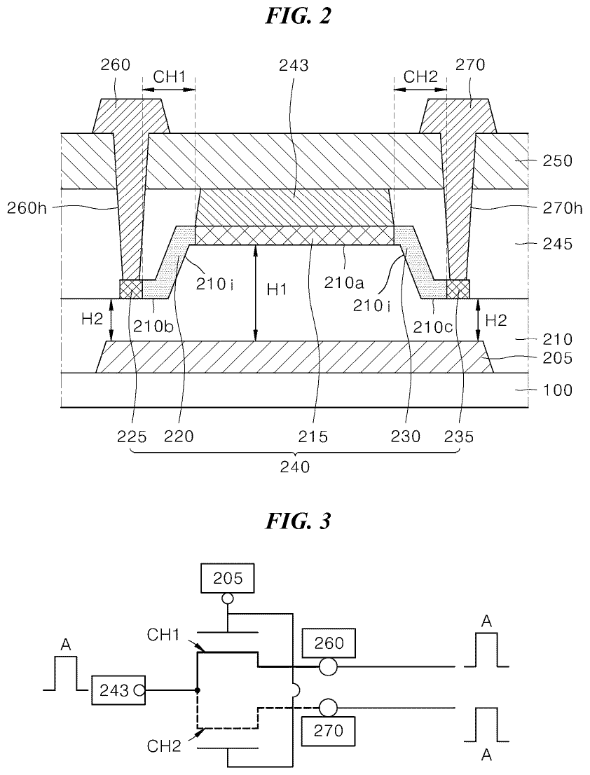

FIG. 2 is a cross-sectional view of a transistor according to an embodiment of the present disclosure. FIG. 3 is a diagram showing signal transmission of a transistor according to an embodiment of the present disclosure. The structure and configuration of each transistor discussed herein according to all embodiments of the present disclosure can be applied to all types of display apparatuses.

Referring to FIG. 2, a gate electrode 205 can be disposed on a substrate 100.

The substrate 100 can include glass or plastic. However, embodiments of the present disclosure are not limited thereto. When the substrate 100 is embodied as the plastic substrate, the plastic substrate can include polyimide. However, embodiments of the present disclosure are not limited thereto.

The gate electrode 205 can be formed as a single layer or a stack of multiple layers made of one of opaque metal materials such as molybdenum (Mo), aluminum (Al), titanium (Ti), or copper (Cu), or an alloy thereof. However, embodiments of the present disclosure are not limited thereto.

The gate electrode 205 of the transistor according to an embodiment of the present disclosure can be embodied as a bottom gate electrode. However, embodiments of the present disclosure are not limited thereto.

An insulating layer can be further included between the substrate 100 and the gate electrode 205. The insulating layer can prevent moisture or foreign substances from the substrate 100 from penetrating into the gate electrode 205 and the semiconductor layer to protect the gate electrode 205 and the semiconductor layer. The insulating layer can be formed as a single layer or a stack of multiple layers made of silicon oxide (SiOₓ) or silicon nitride (SiNₓ). However, embodiments of the present disclosure are not limited thereto. The insulating layer can be, but is not limited to, a buffer layer.

A first insulating layer 210 can be disposed on the gate electrode 205. The first insulating layer 210 can include a first area 210a, a second area 210b, and a third area 210c having different thicknesses. Accordingly, spacing between the gate electrodes 205 and the first area 210a, the second area 210b, and the third area 210c of the first insulating layer 210 can be different from each other.

The first area 210a of the first insulating layer 210 can have a first thickness H1. Each of the second area 210b and the third area 210c of the first insulating layer 210 can have a second thickness H2. The first thickness H1 of the first area 210a of the first insulating layer 210 can be different from the second thickness H2 of each of the second area 210b and the third area 210c thereof. The first thickness H1 of the first area 210a of the first insulating layer 210 can be larger than the second thickness H2 of each of the second area 210b and the third area 210c thereof. The second thickness H2 of the second area 210b and the second thickness H2 the third area 210c can be equal or unequal to each other. However, embodiments of the present disclosure are not limited thereto.

The first insulating layer 210 can be formed as a single layer or a stack of multiple layers made of silicon oxide (SiOx) or silicon nitride (SiNx). However, embodiments of the present disclosure are not limited thereto.

The first area 210a of the first insulating layer 210 can be disposed at a position corresponding to or overlapping a first portion of the gate electrode 205. The second area 210b of the first insulating layer 210 can be disposed at a position corresponding to or overlapping a second portion of the gate electrode 205. For example, the first portion of the gate electrode 205 can include a middle portion, and the second portion of the gate electrode 205 can include each of both opposing side portions in the horizonal direction around the middle portion positioned therebetween.

The first area 210a of the first insulating layer 210 can overlap the middle portion in the horizontal direction of the gate electrode 205 and can have the thickest first thickness H1. The second area 210b of the first insulating layer 210 can overlap one side portion in the horizontal direction of the gate electrode 205 and can have the second thickness H2 that is relatively smaller than the first thickness H1. The third area 210c of the first insulating layer 210 can have the second thickness H2 that is relatively smaller than the first thickness H1 and can overlap the other side portion in the horizontal direction of the gate electrode 205 and can be opposite to the second area 210b.

Accordingly, a vertical level of an upper surface of the first area 210a of the first insulating layer 210 and a vertical level of an upper surface of the second area 210b can be different from each other. The first area 210a and the second area 210b of the first insulating layer 210 can be connected to each other via one inclined surface 210i.

Furthermore, the upper surface of the first area 210a of the first insulating layer 210 and the upper surface of the third area 210c can be positioned at different vertical levels. The first area 210a and the third area 210c of the first insulating layer 210 can be connected to each other via the other inclined surface 210i.

A semiconductor layer 240 can be disposed on the first insulating layer 210. The semiconductor layer 240 can overlap with the gate electrode 205 vertically. For example, the semiconductor layer 240 can be disposed to overlap with the gate electrode 205 in the vertical direction.

The semiconductor layer 240 can be disposed along a profile of the first insulating layer 210 in the conformal manner. However, embodiments of the present disclosure are not limited thereto. For example, the semiconductor layer 240 can be disposed on an upper surface of the first area 210a of the first insulating layer 210 and can extend along a portion of an upper surface of the second area 210b and a portion of an upper surface of the third area 210c.

The semiconductor layer 240 can be disposed on one inclined surface 210i between the first area 210a and the second area 210b of the first insulating layer 210. In addition, the semiconductor layer 240 can be disposed on the other inclined surface 210i between the first area 210a and the third area 210c of the first insulating layer 210.

Accordingly, the semiconductor layer 240 can include different areas having different vertical levels and thus can have a step shape. For example, an upper surface of the first portion of the semiconductor layer 240 disposed on the first area 210a of the first insulating layer 210 can be disposed at a higher position than a position of an upper surface of each of the second portion of the semiconductor layer 240 disposed on the second area 210b of the first insulating layer 210 and the third portion of the semiconductor layer 240 disposed on the third area 210c thereof.

Furthermore, the semiconductor layer 240 can include a first inclined portion 220 disposed along one inclined surface 210i between the first area 210a and the second area 210b of the first insulating layer 210. The semiconductor layer 240 can include a second inclined portion 230 disposed along the other inclined surface 210i between the first area 210a and the third area 210c of the first insulating layer 210.

Accordingly, the semiconductor layer 240 can include at least two steps.

The semiconductor layer 240 can include an oxide semiconductor material. However, embodiments of the present disclosure are not limited thereto. For example, the semiconductor layer 240 can include an oxide semiconductor material such as indium-gallium-zinc-oxide (IGZO) or indium-zinc-oxide (IZO). However, embodiments of the present disclosure are not limited thereto.

A first electrode 243 can be disposed on the semiconductor layer 240. The first electrode 243 can be a source electrode. However, embodiments of the present disclosure are not limited thereto. A portion of the semiconductor layer 240 in contact with the first electrode 243 can be embodied as a first conductivized area 215 (or first conductor/conductive area) of the semiconductor layer 240.

A second insulating layer 245 can be disposed on the first electrode 243. The second insulating layer 245 can be disposed on the semiconductor layer 240. The second insulating layer 245 can cover the semiconductor layer 240. The second insulating layer 245 can be an insulating layer. However, embodiments of the present disclosure are not limited thereto. The second insulating layer 245 can be formed as a single layer or a stack of multiple layers made of silicon oxide (SiOₓ) or silicon nitride (SiNₓ). However, embodiments of the present disclosure are not limited thereto.

A third insulating layer 250 can be disposed on the second insulating layer 245. The third insulating layer 250 can act as a protective layer. However, embodiments of the present disclosure are not limited thereto. The third insulating layer 250 can be formed as a single layer or a stack of multiple layers made of silicon oxide (SiOₓ) or silicon nitride (SiNₓ). However, embodiments of the present disclosure are not limited thereto.

A second electrode 260 and a third electrode 270 can be disposed on the third insulating layer 250. The second electrode 260 can be in contact with and electrically connected to the second portion 225 of the semiconductor layer 240 via a first contact hole 260h extending through the third insulating layer 250 and second insulating layer 245. The second portion 225 of the semiconductor layer 240 in contact with the second electrode 260 can embodied as a second conductivized area (or second conductor/conductive area). The third electrode 270 can be in contact with and be electrically connected the third portion 235 of the semiconductor layer 240 via a second contact hole 270h extending through the third insulating layer 250 and second insulating layer 245. The third portion 235 of the semiconductor layer 240 in contact with the third electrode 270 can be embodied as a third conductivized area (or third conductor/conductive area).

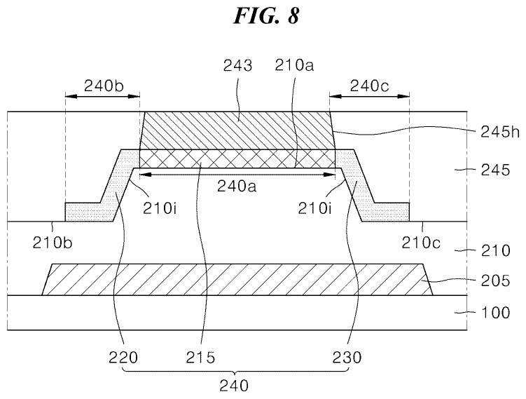

The second electrode 260 and the third electrode 270 can be respectively disposed on both opposing sides of the first electrode 243 interposed therebetween in a plan view. For example, a portion of the semiconductor layer 240 overlapping the first electrode 243 can be referred to as the first portion. One side portion around the first portion of the semiconductor layer 240 overlapping the first electrode 243 can be referred to as the second portion. Further, the other side portion around the first portion of the semiconductor layer 240 overlapping the first electrode 243 can be referred to as the third portion. The second electrode 260 can contact and be electrically connected to the second portion of the semiconductor layer 240 while being disposed on one side of the first electrode 243 in a plan view. The third electrode 270 can contact and be electrically connected to the third portion of the semiconductor layer 240 while being disposed on the other side of the first electrode 243 in a plan view. The first electrode 243, the second electrode 260, and the third electrode 270 will be described later with reference to FIGS. 8 to 10. The second electrode 260 can be a first drain electrode, and the third electrode 270 can be a second drain electrode. However, embodiments of the present disclosure are not limited thereto.

The transistor can be composed of the gate electrode 205, the semiconductor layer 240, the first electrode 243, the second electrode 260, and the third electrode 270 formed in the above manner.

In the transistor according to one embodiment of the present disclosure, at least two channel areas CH1 and CH2 can be formed in a single transistor.

The channel areas CH1 and CH2 can be respectively portions of the semiconductor layer 240 overlapping the gate electrode 205 embodied as the bottom gate electrode in the vertical direction.

The channel areas CH1 and CH2 can include the first channel area CHI and the second channel area CH2. The first inclined portion 220 of the semiconductor layer 240 overlapping with the gate electrode 205 and disposed between the first electrode 243 and the second electrode 260 in the plan view can constitute the first channel area CH1. The second inclined portion 230 of the semiconductor layer 240 that is disposed between the first electrode 243 and the third electrode 270 and overlaps the gate electrode 205 can constitute the second channel area CH2.

According to one embodiment of the present disclosure, the transistor can include a structure in which the second electrode 260 and the third electrode 270 are respectively disposed on both opposing sides of the first electrode 243 in a plan view. Accordingly, the channel areas CH1 and CH2 can include the first channel area CHI disposed between the first electrode 243 and the second electrode 260 and the second channel area CH2 disposed between the first electrode 243 and the third electrode 270.

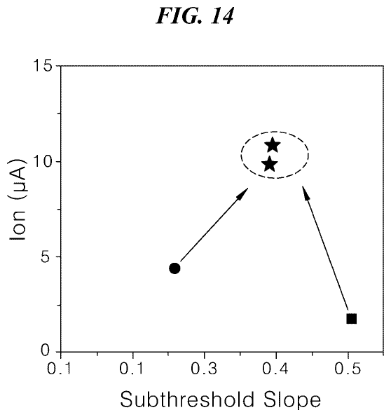

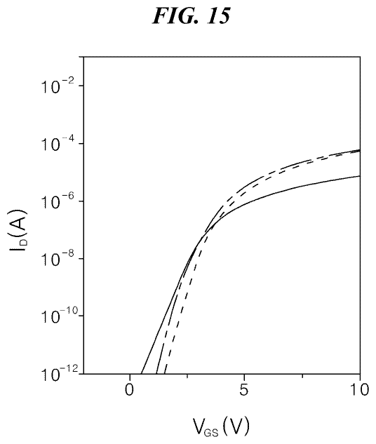

Accordingly, a structure in which at least two transistors are connected in parallel to each other can be implemented. Driving current Ion flowing between the first electrode 243 and the second electrode 260 can have a first current amount. In addition, driving current Ion flowing between the first electrode 243 and the third electrode 270 can have a second current amount. A combination of at least two transistors connected in parallel to each other can have a third current amount as a sum of the first current amount and the second current amount as driving current Ion thereof. Accordingly, the transistor according to an embodiment of the present disclosure can secure an increased current amount of the driving current Ion in a non-changed area. The increased current amount is described later with reference to FIG. 14 and FIG. 15.

Furthermore, a single transistor according to an embodiment of the present disclosure can control at least one signal using the at least two channel areas CH1 and CH2. The signal controlled through the channel areas CH1 and CH2 can be the data signal. However, embodiments of the present disclosure are not limited thereto.

For example, referring to FIG. 3, a signal of a first waveform A supplied from the first electrode 243 can be transmitted to the first channel area CH1 such that the signal of the first waveform A can be transmitted to the second electrode 260. In addition, the signal of the first waveform A supplied from the first electrode 243 can be transmitted to the second channel area CH2 positioned at a different location from that of the first channel area CH1 such that the signal of the first waveform A can be transmitted to the third electrode 270.

For example, the data signal can be applied to each of the sub-pixels SP1, SP2, and SP3 (refer to FIG. 1) of the display area AA (refer to FIG. 1), the sub-pixels SP1, SP2, and SP3 can emit light beams of red (R), green (G), and blue (B) colors, respectively. The signal of the first waveform A transmitted to the first channel area CH1 can be an on signal that operates the sub-pixel SP1, SP2, or SP3 connected to one of the plurality of data lines DL. In addition, the signal of the first waveform A transmitted to the second channel area CH2 can be an on signal that operates the sub-pixel SP1, SP2, or SP3 connected to another data line DL adjacent to one of the plurality of data lines DL. Accordingly, at least two adjacent data lines DL can carry the single data signal to operate at least two sub-pixels in the display area AA.

In this case, the signal of the first waveform A transmitted to each of the first channel area CH1 and the second channel area CH2 can be transmitted thereto at the same time. However, embodiments of the present disclosure are not limited thereto. For example, the signal of the first waveform A transmitted to each of the first channel area CH1 and the second channel area CH2 can be transmitted thereto at different timings.

Accordingly, a single data signal can be transmitted as two data signals in a separate manner via the different first channel area CH1 and second channel area CH2 defined in the different areas in the single transistor. Accordingly, an area size occupied by the transistor can be reduced in the case of the same area of the display apparatus.

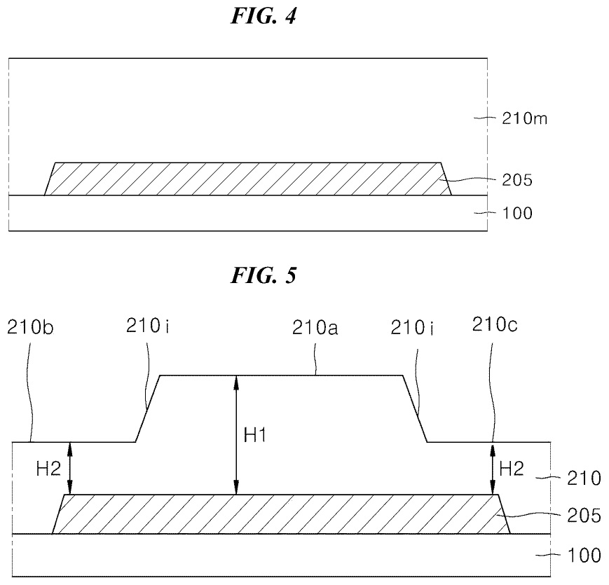

FIGS. 4 to 10 are diagrams showing a method for manufacturing a transistor according to one or more embodiments of the present disclosure. The same reference numerals are given to components identical or substantially identical to those of the transistor as described above with reference to FIG. 2, and descriptions thereof are simplified or omitted.

Referring to FIG. 4, the gate electrode 205 can be disposed on the substrate 100. A first insulating material layer 210m can be formed on the gate electrode 205. The first insulating material layer 210m can be formed to have a sufficient thickness for formation of a step shape thereafter. The first insulating material layer 210m can be formed as a single layer or a stack of multiple layers made of silicon oxide (SiOₓ) or silicon nitride (SiNₓ). However, embodiments of the present disclosure are not limited thereto.

Referring to FIG. 5, the first insulating material layer 210m can be etched to form the first insulating layer 210. The first insulating layer 210 can include the first area 210a, the second area 210b, and the third area 210c having different thicknesses. Accordingly, spacing between the gate electrodes 205 and the first area 210a, the second area 210b, and the third area 210c of the first insulating layer 210 can be different from each other. The first area 210a of the first insulating layer 210 can have a first thickness H1. Each of the second area 210b and the third area 210c of the first insulating layer 210 can have a second thickness H2. The first thickness H1 of the first area 210a of the first insulating layer 210 can be different from the second thickness H2 of each of the second area 210b and the third area 210c thereof. The first thickness H1 of the first area 210a of the first insulating layer 210 can be larger than the second thickness H2 of each of the second area 210b and the third area 210c thereof. The second thickness H2 of the second area 210b and the second thickness H2 the third area 210c can be equal or unequal to each other. However, embodiments of the present disclosure are not limited thereto.

The first insulating layer 210 can include the first area 210a, the second area 210b, and the third area 210c having different thicknesses such that the first insulating layer 210 can include at least two steps. For example, the upper surface of the first area 210a and the upper surface of the second area 210b of the first insulating layer 210 can be positioned at different vertical levels. Furthermore, the upper surface of the first area 210a and the upper surface of the third area 210c can be positioned at different vertical levels.

The first area 210a of the first insulating layer 210 can be disposed at a position corresponding to or overlapping a first portion of the gate electrode 205. The second area 210b of the first insulating layer 210 can be disposed at a position corresponding to or overlapping a second portion of the gate electrode 205. For example, the first portion of the gate electrode 205 can include a middle portion, and the second portion of the gate electrode 205 can include each of both opposing side portions in the horizonal direction around the middle portion positioned therebetween.

The first area 210a of the first insulating layer 210 can overlap the middle portion in the horizontal direction of the gate electrode 205 and can have the thickest first thickness H1. The second area 210b of the first insulating layer 210 can overlap one side portion in the horizontal direction of the gate electrode 205 and can have the second thickness H2 that is relatively smaller than the first thickness H1. The third area 210c of the first insulating layer 210 can have the second thickness H2 that is relatively smaller than the first thickness H1 and can overlap the other side portion in the horizontal direction of the gate electrode 205 and can be opposite to the second area 210b.

Accordingly, a vertical level of an upper surface of the first area 210a of the first insulating layer 210 and a vertical level of an upper surface of the second area 210b can be different from each other. The first area 210a and the second area 210b of the first insulating layer 210 can be connected to each other via one inclined surface 210i.

Furthermore, the upper surface of the first area 210a of the first insulating layer 210 and the upper surface of the third area 210c can be positioned at different vertical levels. The first area 210a and the third area 210c of the first insulating layer 210 can be connected to each other via the other inclined surface 210i.

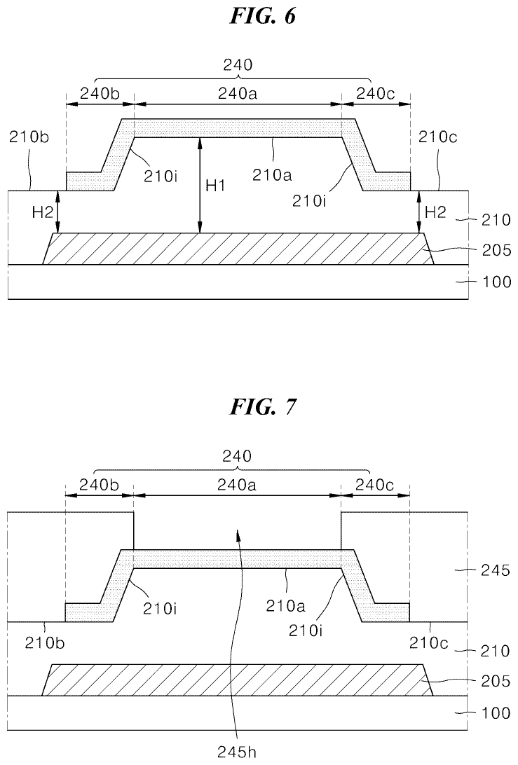

Referring to FIG. 6, the semiconductor layer 240 can be formed on the first insulating layer 210. The semiconductor layer 240 can overlap with the gate electrode 205 vertically. For example, the semiconductor layer 240 can be disposed to overlap with the gate electrode 205 in the vertical direction. The semiconductor layer 240 can be disposed along a profile of the first insulating layer 210 in the conformal manner. However, embodiments of the present disclosure are not limited thereto. For example, the semiconductor layer 240 can be disposed on an upper surface of the first area 210a of the first insulating layer 210 and can extend along a portion of an upper surface of the second area 210b and a portion of an upper surface of the third area 210c. The semiconductor layer 240 can be disposed on one inclined surface 210i between the first area 210a and the second area 210b of the first insulating layer 210. In addition, the semiconductor layer 240 can be disposed on the other inclined surface 210i between the first area 210a and the third area 210c of the first insulating layer 210.

Accordingly, the semiconductor layer 240 can include different areas having different vertical levels and thus can have a step shape. For example, an upper surface of the first portion of the semiconductor layer 240 disposed on the first area 210a of the first insulating layer 210 can be disposed at a higher position than a position of an upper surface of each of the second portion of the semiconductor layer 240 disposed on the second area 210b of the first insulating layer 210 and the third portion of the semiconductor layer 240 disposed on the third area 210c thereof. Furthermore, the semiconductor layer 240 can include a first inclined portion 220 disposed along one inclined surface 210i between the first area 210a and the second area 210b of the first insulating layer 210. The semiconductor layer 240 can include a second inclined portion 230 disposed along the other inclined surface 210i between the first area 210a and the third area 210c of the first insulating layer 210. Accordingly, the upper surface of the first portion 240a of the semiconductor layer 240 can be disposed at a higher position than that of each of the second portion 240b and the third portion 240c of the semiconductor layer 240. Accordingly, the semiconductor layer 240 can include at least two steps.

The semiconductor layer 240 can include an oxide semiconductor material. However, embodiments of the present disclosure are not limited thereto. For example, the semiconductor layer 240 can include an oxide semiconductor material such as indium-gallium-zinc-oxide (IGZO) or indium-zinc-oxide (IZO). However, embodiments of the present disclosure are not limited thereto.

Referring to FIG. 7, the second insulating layer 245 can be formed on the semiconductor layer 240. The second insulating layer 245 can have an opening 245h defined therein that exposes the first portion 240a of the semiconductor layer 240. The second insulating layer 245 can cover the second portion 240b and the third portion 240c of the semiconductor layer 240 such that the second portion 240b and the third portion 240c are not exposed.

Referring to FIG. 8, the first electrode 243 can be formed on the second insulating layer 245. The first electrode 243 can fill the opening 245h of the second insulating layer 245. The first electrode 243 can be in contact with the first portion 240a of the semiconductor layer 240.

The first portion 240a of the semiconductor layer 240 in contact with the first electrode 243 can be embodied as the first conductivized area 215. The second portion 240b of the semiconductor layer 240 can include the first inclined portion 220 disposed on one inclined surface 210i of the first insulating layer 210 and a flat portion disposed on a portion of an upper surface of the second area 210b of the first insulating layer 210. The third portion 240c of the semiconductor layer 240 can include the second inclined portion 230 disposed on the other inclined surface 210i of the first insulating layer 210 and a flat portion disposed on a portion of an upper surface of the third area 210c of the first insulating layer 210.

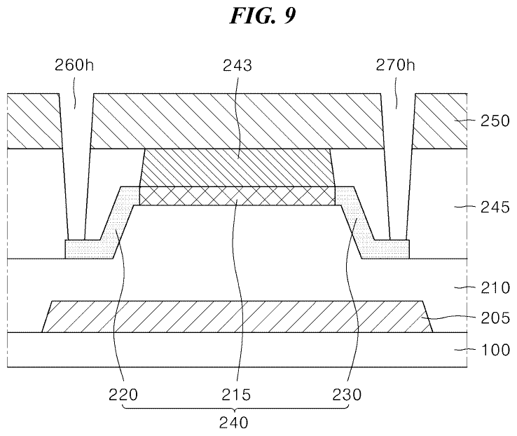

Referring to FIG. 9, the third insulating layer 250 can be formed on the second insulating layer 245. The third insulating layer 250 can be formed on the first electrode 243. The third insulating layer 250 can cover the first electrode 243. The third insulating layer 250 can have the first contact hole 260h and the second contact hole 270h received therein. The first contact hole 260h can extend through the third insulating layer 250 and the second insulating layer 245 so as to expose a portion of the upper surface of the semiconductor layer 240. The second contact hole 270h can extend through the third insulating layer 250 and the second insulating layer 245 so as to expose a portion of the upper surface of the semiconductor layer 240. The second contact hole 270h and the first contact hole 260h can be arranged to be spaced apart from each other while the first electrode 243 is interposed therebetween in a plan view.

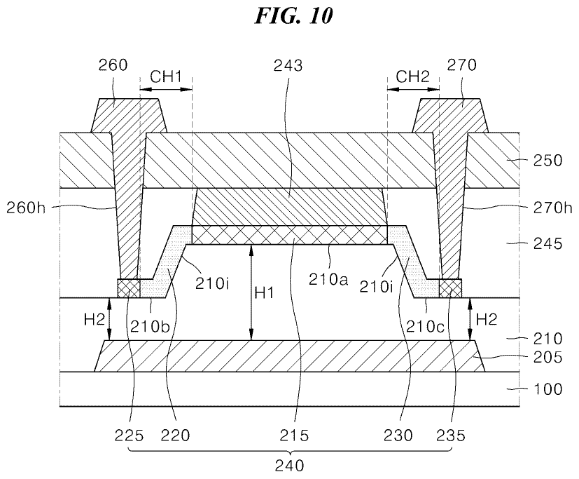

Referring to FIG. 10, the second electrode 260 and the third electrode 270 can be disposed on the third insulating layer 250.

The second electrode 260 can fill the first contact hole 260h. A lower surface of the second electrode 260 can contact and be electrically connected to the second portion 225 of the semiconductor layer 240. The second portion 225 of the semiconductor layer 240 electrically connected to the second electrode 260 can be embodied as the second conductivized area. The third electrode 270 can fill the second contact hole 270h. A lower surface of the third electrode 270 can contact and be electrically connected to the third portion 235 of the semiconductor layer 240. The third portion 235 of the semiconductor layer 240 electrically connected to the third electrode 270 can be embodied as the third conductivized area.

In this way, the channel areas CH1 and CH2 including the first channel area CH1 and the second channel area CH2 can be formed. A portion of the semiconductor layer 240 overlapping with the gate electrode 205 vertically and positioned between the first electrode 243 and the second electrode 260 in the plan view can constitute the first channel area CH1. For example, the first channel area CH1 can include the first inclined portion 220 of the semiconductor layer 240.

A portion of the semiconductor layer 240 overlapping with the gate electrode 205 vertically and positioned between the first electrode 243 and the third electrode 270 in the plan view can constitute the second channel area CH2. For example, the second channel area CH2 can include the second inclined portion 230 of the semiconductor layer 240.

According to an embodiment of the present disclosure, in this way, the transistor including the gate electrode 205, the semiconductor layer 240, the first electrode 243, the second electrode 260, and the third electrode 270 can be manufactured.

According to one embodiment of the present disclosure, the transistor can include a structure in which the second electrode 260 and the third electrode 270 are respectively disposed on both opposing sides of the first electrode 243 in a plan view. Accordingly, the channel areas CH1 and CH2 can include the first channel area CH1 disposed between the first electrode 243 and the second electrode 260 and the second channel area CH2 disposed between the first electrode 243 and the third electrode 270. That is, in the single transistor, different at least two channels including the first channel area CH1 and the second channel area CH2 can be realized.

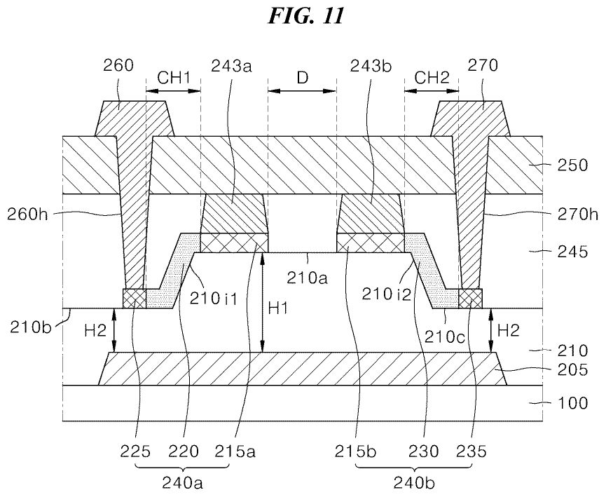

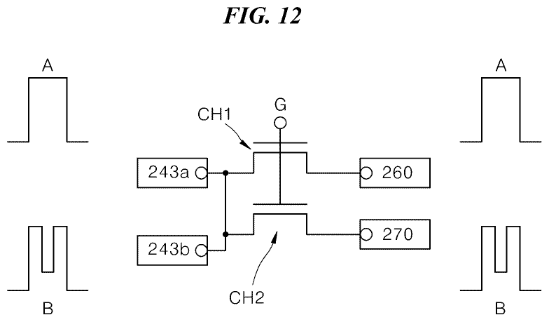

FIG. 11 is a cross-sectional view of a transistor according to another embodiment of the present disclosure. FIG. 12 is a diagram showing signal transmission of a transistor according to another embodiment of the present disclosure. The same reference numerals are given to the same or substantially the same components as those of the transistor described above with reference to FIG. 2, and descriptions thereof are simplified or omitted.

Referring to FIG. 11, the gate electrode 205 can be disposed on the substrate 100. The gate electrode 205 of the transistor according to an embodiment of the present disclosure can be embodied as a bottom gate electrode. However, embodiments of the present disclosure are not limited thereto.

The first insulating layer 210 can be disposed on the gate electrode 205. The first insulating layer 210 can include the first area 210a, the second area 210b, and the third area 210c having different thicknesses. Accordingly, spacing between the gate electrodes 205 and the first area 210a, the second area 210b, and the third area 210c of the first insulating layer 210 can be different from each other.

The first area 210a of the first insulating layer 210 can have a first thickness H1. Each of the second area 210b and the third area 210c of the first insulating layer 210 can have a second thickness H2. The first thickness H1 of the first area 210a of the first insulating layer 210 can be different from the second thickness H2 of each of the second area 210b and the third area 210c thereof. The first thickness H1 of the first area 210a of the first insulating layer 210 can be larger than the second thickness H2 of each of the second area 210b and the third area 210c thereof. The second thickness H2 of the second area 210b and the second thickness H2 the third area 210c can be equal or unequal to each other. However, embodiments of the present disclosure are not limited thereto.

The first area 210a of the first insulating layer 210 can be disposed at a position corresponding to or overlapping a first portion of the gate electrode 205. The second area 210b of the first insulating layer 210 can be disposed at a position corresponding to or overlapping the second portion of the gate electrode 205. The third area 210c of the first insulating layer 210 can be disposed at a position corresponding to or overlapping the third portion of the gate electrode 205.

The upper surface of the first area 210a of the first insulating layer 210 and each of the upper surfaces of the second area 210b and the third area 210c thereof can be positioned at different vertical levels. The upper surfaces of the second area 210b and the third area 210c can be positioned at the same vertical level. The upper surfaces of the first area 210a and the second area 210b of the first insulating layer 210 can be connected to each other via the first inclined surface 210i1. Furthermore, the upper surfaces of the first area 210a and the third area 210c of the first insulating layer 210 can be connected to each other via the second inclined surface 210i2.

One or more semiconductor layers 240a and 240b can be disposed on the first insulating layer 210. Each of the one or more semiconductor layers 240a and 240b can be disposed to overlap with the gate electrode 205. For example, each of the one or more semiconductor layers 240a and 240b can be disposed to overlap with the gate electrode 205 in the vertical direction.

The semiconductor layer 240a and 240b can include the first semiconductor layer 240a and the second semiconductor layer 240b. The first semiconductor layer 240a and the second semiconductor layer 240b can be arranged to be spaced apart from each other by a spacing D defined therebetween in a plan view of the transistor. A portion of the upper surface of the first area 210a of the first insulating layer 210 can be exposed through the spacing D.

The first semiconductor layer 240a and the second semiconductor layer 240b can be arranged in a symmetrical manner with each other around the spacing D defined therebetween. However, embodiments of the present disclosure are not limited thereto.

The first semiconductor layer 240a can be disposed to overlap one side portion of the gate electrode 205. For example, the first semiconductor layer 240a can be disposed to overlap one side portion of the gate electrode 205 in a vertical direction. The second semiconductor layer 240a can be disposed to overlap the gate electrode 205 and can be positioned at a position spaced apart from the first semiconductor layer 240a in a plan view. For example, the second semiconductor layer 240a can be disposed to overlap the other side portion of the gate electrode 205 in a vertical direction and can be positioned at a position spaced apart from the first semiconductor layer 240a in the plan view.

Each of the first semiconductor layer 240a and the second semiconductor layer 240b can be disposed along a profile of the upper surface of the first insulating layer 210 in the conformal manner. For example, the first semiconductor layer 240a can be disposed on one side portion of the first area 210a of the first insulating layer 210 and can be disposed on the first inclined surface 210i1 and on a portion of the second area 210b of the first insulating layer 210 in the conformal manner. The second semiconductor layer 240b can be disposed on the other side portion of the first area 210a of the first insulating layer 210 and can be disposed on the second inclined surface 210i2 and a portion of the third area 210c of first insulating layer 210 in the conformal manner.

Accordingly, each of the first semiconductor layer 240a and the second semiconductor layer 240b can include different areas having different vertical levels and thus can have a step shape. For example, an upper surface of a portion of the first semiconductor layer 240a disposed on one side portion of the first area 210a of the first insulating layer 210 can be disposed at a higher vertical level than a vertical level of an upper surface of a portion of the first semiconductor layer 240a disposed on the second area 210b of the first insulating layer 210. The first semiconductor layer 240a can include the first inclined portion 220 disposed along and on the first inclined surface 210i1 between the first area 210a and the second area 210b of the first insulating layer 210.

Furthermore, an upper surface of a portion of the second semiconductor layer 240b disposed on the other side portion of the first area 210a of the first insulating layer 210 can be disposed at a higher vertical level than a vertical level of an upper surface of a portion of the second semiconductor layer 240b disposed on the third area 210c of the first insulating layer 210. The second semiconductor layer 240b can include the second inclined portion 230 disposed along and on the second inclined surface 21012 between the first area 210a and the third area 210c of the first insulating layer 210.

Accordingly, each of the first semiconductor layer 240a and the second semiconductor layer 240b can include the step.

Each of the first semiconductor layer 240a and the second semiconductor layer 240b can include an oxide semiconductor material. However, embodiments of the present disclosure are not limited thereto. For example, each of the first semiconductor layer 240a and the second semiconductor layer 240b can include indium-gallium-zinc-oxide or indium-zinc-oxide. However, embodiments of the present disclosure are not limited thereto.

A first electrode 243a can be disposed on the first semiconductor layer 240a. The first semiconductor layer 240a can include a first conductivized area 215a (or first conductor/conductive area) that contacts the first electrode 243a. A fourth electrode 243b can be disposed on the second semiconductor layer 240b. The second semiconductor layer 240b can include a fourth conductivized area 215a (or fourth conductor/conductive area) contacting the fourth electrode 243b. The first electrode 243a can be a first source electrode, and the fourth electrode 243b can be a second source electrode. However, embodiments of the present disclosure are not limited thereto.

The second insulating layer 245 can be disposed on the first electrode 243a and the fourth electrode 243b. The second insulating layer 245 can cover the first semiconductor layer 240a and the second semiconductor layer 240b. The second insulating layer 245 can be an interlayer insulating layer. However, embodiments of the present disclosure are not limited thereto. The second insulating layer 245 can be formed as a single layer or a stack of multiple layers made of silicon oxide (SiOₓ) or silicon nitride (SiNₓ). However, embodiments of the present disclosure are not limited thereto.

The third insulating layer 250 can be disposed on the second insulating layer 245. The third insulating layer 250 can act as a protective layer. However, embodiments of the present disclosure are not limited thereto. The third insulating layer 250 can be made of an organic insulating material. However, embodiments of the present disclosure are not limited thereto.

The second electrode 260 and the third electrode 270 can be disposed on the third insulating layer 250. The second electrode 260 can be electrically connected to the second portion 225 of the first semiconductor layer 240a via the first contact hole 260h. The second portion 225 of the first semiconductor layer 240a electrically connected to the second electrode 260 can be embodied as the second conductivized area. The second electrode 260 can be a first drain electrode. However, embodiments of the present disclosure are not limited thereto. The third electrode 270 can be electrically connected to the second portion 235 of the second semiconductor layer 240b via the second contact hole 270h. The second portion 235 of the second semiconductor layer 240b electrically connected to the second electrode 270 can be embodied as the third conductivized area. The third electrode 270 can be a second drain electrode. However, embodiments of the present disclosure are not limited thereto.

One transistor can be composed of the gate electrode 205, the first semiconductor layer 240a, the first electrode 243a, and the second electrode 260 formed in this manner. Furthermore, another transistor can be composed of the gate electrode 205, the second semiconductor layer 240b, the fourth electrode 243b, and the third electrode 270. One or more transistors can be implemented using the first semiconductor layer 240a and the second semiconductor layer 240b spaced apart from each other by the spacing D therebetween and overlapping one gate electrode 205 vertically.

A portion of the first semiconductor layer 240a overlapping the gate electrode 205 and a portion of the second semiconductor layer 240b overlapping the gate electrode 205 can act as the channel areas CH1 and CH2, respectively.

The channel areas CH1 and CH2 can include the first channel area CH1 and the second channel area CH2. A portion of the first semiconductor layer 240a overlapping the gate electrode 205 and disposed between the first electrode 243a and the second electrode 260 can constitute the first channel area CH1. The first channel area CH1 can include the first inclined portion 220 of the semiconductor layer 240 which overlaps the gate electrode 205. A portion of the second semiconductor layer 240b overlapping the gate electrode 205 and disposed between the fourth electrode 243b and the third electrode 270 can constitute the second channel area CH2. The second channel area CH2 can include the second inclined portion 230 of the semiconductor layer 240 overlapping the gate electrode 205.

One or more signals can be controlled through at least two channel areas CH1 and CH2. The signal controlled through the channel areas CH1 and CH2 can be a data signal. However, embodiments of the present disclosure are not limited thereto. For example, referring to FIG. 12, the first electrode 243a can transmit a signal of a first waveform A to the first channel area CH1, and the fourth electrode 243b can transmit a signal of a second waveform B to the second channel area CH2. The signal of the first waveform A and the signal of the second waveform B can be different signals. For example, the data signal can be applied to each of the sub-pixels SP1, SP2, and SP3 (see FIG. 1) to emit each of light beams of red (R), green (G), and blue (B) colors. The signal of the first waveform A transmitted to the first channel area CH1 can be an on signal that operates each of the sub-pixels SP1, SP2, and SP3. The signal of the second waveform B can be a switching signal that controls each of the sub-pixels SP1, SP2, and SP3 to emit light of at least one color among red (R), green (G), and blue (B). Accordingly, luminance of light of one color among red (R), green (G), and blue (B) colors can be increased or decreased in the display area AA (see FIG. 1) based on the switching signal.

The signal of the first waveform A supplied from the first electrode 243a can be transmitted to the first channel area CH1 such that the signal of the first waveform A can be transmitted to the second electrode 260. Furthermore, the signal of the second waveform B supplied from the fourth electrode 243b can be transmitted to the second channel area CH2 positioned at a different location from that of the first channel area CH1 such that the signal of the second waveform B can be transmitted to the third electrode 270.

In this case, the signal of the first waveform A and the signal of the second waveform B respectively transmitted to the first channel area CH1 and the second channel area CH2 can be transmitted thereto at different timings. However, embodiments of the present disclosure are not limited thereto.

At least two different data signals can be respectively transmitted to different locations through the first channel areas CH1 and the second channel area CH2 different from each other and positioned at different locations in the single transistor. Accordingly, the area size occupied by the transistor can be reduced in the case of the same area of the display apparatus.

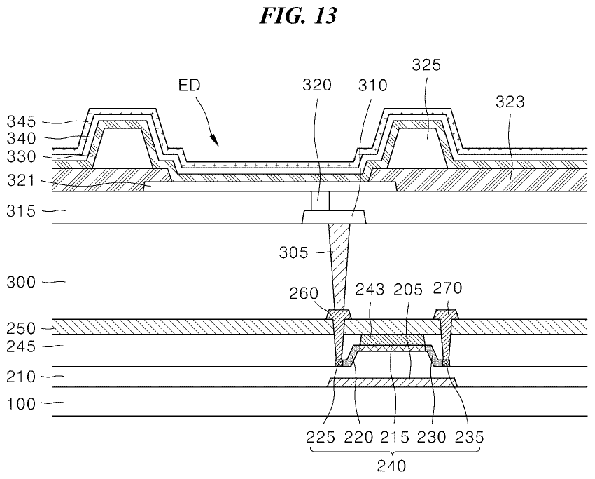

FIG. 13 is a cross-sectional view of a display apparatus including a transistor according to an embodiment of the present disclosure, and illustrates a transistor according to an embodiment of the present disclosure by way of example. However, embodiments of the present disclosure are not limited thereto.

Referring to FIG. 13, the gate electrode 205 can be disposed on the substrate 100. The gate electrode 205 can be embodied as the bottom gate electrode. However, embodiments of the present disclosure are not limited thereto.

The first insulating layer 210 can be disposed on the gate electrode 205. The first insulating layer 210 can include at least one step. The semiconductor layer 240 can be disposed on the first insulating layer 210. The semiconductor layer 240 can be disposed along the surface profile of the first insulating layer 210 in the conformal manner. Accordingly, the semiconductor layer 240 can include at least one step.

The first electrode 243 can be disposed on the semiconductor layer 240. The first electrode 243 can be electrically connected to the first portion 215 of the semiconductor layer 240. The first electrode 243 can be a source electrode. However, embodiments of the present disclosure are not limited thereto.

The second insulating layer 245 can be disposed on the semiconductor layer 240 and the first electrode 243. The second insulating layer 245 can be an interlayer insulating layer. However, embodiments of the present disclosure are not limited thereto. The third insulating layer 250 can be disposed on the second insulating layer 245. The third insulating layer 250 can act as a protective layer. However, embodiments of the present disclosure are not limited thereto.

The second electrode 260 and the third electrode 270 can be disposed on the third insulating layer 250. The second electrode 260 can extend through the third insulating layer 250 and the second insulating layer 245 so as to be electrically connected to the second portion 225 of the semiconductor layer 240. The third electrode 270 can extend through the third insulating layer 250 and the second insulating layer 245 so as to be electrically connected to the third portion 235 of the semiconductor layer 240.

A first planarization layer 300 can be disposed on the third insulating layer 250. The first planarization layer 300 can cover the second electrode 260 and the third electrode 270. The first planarization layer 300 can planarize a step generated by the underlying circuit element including the transistor. The first planarization layer 300 can include an organic insulating material such as an acryl resin, an epoxy resin, a phenolic resin, a polyamide resin, or a polyimide resin. However, embodiments of the present disclosure are not limited thereto.

A first connection electrode 310 can be disposed on the first planarization layer 300. The first connection electrode 310 can contact a first contact electrode 305 that extends through the first planarization layer 300 so as to be electrically connected to the second electrode 260. However, embodiments of the present disclosure are not limited thereto. In another example, the first connection electrode 310 can be electrically connected to the third electrode 270.

A second planarization layer 315 can be disposed on the first planarization layer 300. The second planarization layer 315 can have a contact hole defined therein that exposes a portion of an upper surface of the first connection electrode 310. The contact hole extending through the second planarization layer 315 can be filled with a second contact electrode 320. A lower surface of the second contact electrode 320 can be electrically connected to the first connection electrode 310.

A plurality of light-emitting elements ED can be disposed on the second planarization layer 315. In one example, the light-emitting element ED can be an organic light-emitting element. However, embodiments of the present disclosure are not limited thereto, and various types of light-emitting elements can be used. For example, the light-emitting element ED can include a quantum dot light-emitting element, an inorganic light-emitting element, a micro LED, or a mini LED. However, embodiments of the present disclosure are not limited thereto. Each of the plurality of light-emitting elements ED can include an anode electrode 321, a light-emitting layer 330, and a cathode electrode 340. The anode electrode 321 can be a pixel electrode, and the cathode electrode 340 can be a counter electrode. However, embodiments of the present disclosure are not limited thereto.

The anode electrode 321 can be disposed on the second planarization layer 315. A lower surface of the anode electrode 321 can be in contact with the upper surface of the second contact electrode 320. Accordingly, the anode electrode 321 can be electrically connected to the second electrode 260 of the transistor via the second contact electrode 320 and the first contact electrode 305. However, embodiments of the present disclosure are not limited thereto. In another example, the anode electrode 321 can be electrically connected to the third electrode 270.

The anode electrode 321 can include a metal oxide such as indium tin oxide (ITO) or indium zinc oxide (IZO). However, embodiments of the present disclosure are not limited thereto. Alternatively, the anode electrode 321 can include a single-layer or multi-layer structure including a reflective metal film made of silver (Ag), aluminum (Al), gold (Au), nickel (Ni), chromium (Cr), and compounds thereof. However, embodiments of the present disclosure are not limited thereto.

A bank 323 can be disposed on the second planarization layer 315. The bank 323 can distinguish the sub-pixels from each other. To this end, the bank 323 can be formed to cover an edge of the anode electrode 321. Furthermore, the bank 323 can prevent light beams of different colors output from adjacent sub-pixels from being mixed with each other. The bank 323 can include an organic insulating film made of, for example, polyimide or epoxy. However, embodiments of the present disclosure are not limited thereto. For example, the bank 323 can be made of a material including a black pigment, or an organic material such as benzocyclobutene resin, epoxy resin, polyimide resin, acryl resin, or a photosensitive polymer. However, embodiments of the present disclosure are not limited thereto. When the bank 323 is made of a material including a black pigment or a black dye, the bank can be embodied as a black bank. When the bank 323 is made of a material including a black pigment or a black dye, the bank can block light from the outside or light reflected from the outside, so that the luminance of the display apparatus can be further improved.

A spacer 325 can be disposed on the bank 323. The spacer 325 can include the same material as that of the bank 323. However, embodiments of the present disclosure are not limited thereto.

The light-emitting layer 330 can be disposed on the anode electrode 321. In one example, the light-emitting layer 330 in each of different sub-pixels can include an organic material that emits a light beam of each of different colors.

The light-emitting layer 330 can include a stack structure including a Hole Transporting Layer (HTL), an Emission Material Layer (EML), an Electron Transporting Layer (ETL), a Hole Blocking Layer (HBL), a Hole Injecting Layer (HIL), an Electron Blocking Layer (EBL), and an Electron Injecting Layer (EIL). However, embodiments of the present disclosure are not limited thereto. When the light-emitting layer 330 includes the stack structure, the stack structure can include one or more stack structures. However, embodiments of the present disclosure are not limited thereto. For example, a charge generation layer can be further disposed between adjacent stack structures. The charge generation layer can include a P-type charge generation layer and an N-type charge generation layer. The light-emitting layer 330 can emit light under recombination of holes injected from the anode electrode 321 and electrons injected from the cathode electrode 340.

The cathode electrode 340 can be disposed on the light-emitting layer 330. The cathode electrode 340 can be formed to cover the light-emitting layer 330. The cathode electrode 340 can be commonly disposed across the plurality of pixels. A capping layer 345 can be disposed on the cathode electrode 340.

The transistor according to some embodiments of the present disclosure can secure an increased amount of the driving current Ion across the same area. This increased current amount can be identified with reference to FIG. 14. In addition, the transistor according to some embodiments of the present disclosure can prevent a threshold voltage from changing.

FIG. 14 and FIG. 15 are current-voltage graphs according to some embodiments of the present disclosure.

In FIG. 14, a first experimental example is indicated by a circle, a second experimental example is indicated as a square, and an embodiment is indicated as a star. In FIG. 14, a horizontal axis denotes an S-factor value, and a vertical axis denotes the current amount of the driving current Ion (microampere: μA). The S-factor is referred to as “subthreshold slope” and indicates a voltage required when the current increases by 10 times. In a graph (I-V curve) showing characteristics of a drain current relative to a gate voltage, the S-factor value is a reciprocal value of a slope of the graph (I-V curve) in a range below the threshold voltage.

Referring to FIG. 14, it can be identified that the amount of the driving current Ion is increased in the transistor according to an embodiment of the present disclosure in each of the first and second experimental examples. In this regard, in the first experimental example, a channel area has a planar structure, and the thickness of the first insulating layer is 500 Å. In the second experimental example, a channel area has a planar structure, and the thickness of the first insulating layer is 4000 Å.

In this regard, in one transistor of an embodiment of the present disclosure, at least two channel areas can be defined due to the semiconductor layer including one or more steps. The thickness of the first insulating layer in FIG. 14 does not limit the scope of the present disclosure.

In FIG. 15, a solid line refers to Comparative Example, a dashed line refers to Present Example 1 of the present disclosure, and a dotted line refers to Present Example 2 of the present disclosure. In FIG. 15, a horizontal axis denotes a gate voltage V_{GS} (V) to be applied to the transistor, and a vertical axis denotes a drain current I_{D} (A).

Referring to FIG. 15, in the Comparative Example, the drain-source current Ids can decrease even when the same reference gate voltage V_{GS}=5 V is applied. This means that the threshold voltage change. Thus, it can be difficult to secure the high current amount. In this regard, it can be identified that in Present Examples 1 and 2 of the present disclosure, the drain-source current Ids increases when the same reference gate voltage V_{GS}=5 V is applied. Accordingly, in Present Examples of the present disclosure, the high current can be stably secured.

A transistor and a display apparatus including the same according to various embodiments of the present disclosure can be described as follows.

A first aspect of the present disclosure provides a transistor comprising: a substrate; a gate electrode disposed on the substrate; a first insulating layer disposed on the gate electrode; and a semiconductor layer disposed on the first insulating layer so as to overlap the gate electrode in a vertical direction, wherein an upper surface of the first insulating layer includes at least one step.

In accordance with some embodiments of the transistor of the first aspect, wherein the semiconductor layer is disposed on the upper surface of the first insulating layer in a conformal manner.

In accordance with some embodiments of the transistor of the first aspect, the first insulating layer includes a first area, a second area, and a third area having different thicknesses, wherein the first area of the first insulating layer has a first thickness based on the gate electrode, wherein each of the second area and the third area of the first insulating layer has a second thickness different from the first thickness based on the gate electrode.

In accordance with some embodiments of the transistor of the first aspect, the first thickness is larger than the second thickness, wherein the second thickness of the second area and the second thickness of the third area are equal or unequal to each other.

In accordance with some embodiments of the transistor of the first aspect, the first insulating layer includes: a first inclined surface connecting an upper surface of the first area and an upper surface the second area of the first insulating layer to each other: and a second inclined surface connecting an upper surface of the first area and an upper surface the third area of the first insulating layer to each other.

In accordance with some embodiments of the transistor of the first aspect, the semiconductor layer is disposed on the first area of the first insulating layer, the first inclined surface, the second inclined surface, a portion of the second area, and a portion of the third area.

In accordance with some embodiments of the transistor of the first aspect, the semiconductor layer includes: a first portion disposed on the first area of the first insulating layer; a second portion disposed on the portion of the second area; a third portion disposed on the portion of the third area; a first inclined portion disposed on the first inclined surface; and a second inclined portion disposed on the second inclined surface, wherein a vertical level of the first portion is higher than a vertical level of each of the second portion and the third portion.

In accordance with some embodiments of the transistor of the first aspect, the semiconductor layer includes an oxide semiconductor.

In accordance with some embodiments of the transistor of the first aspect, the transistor further comprises: a first electrode disposed on and contacting the first portion of the semiconductor layer; a second electrode contacted to a second portion of the semiconductor layer on one side of the first electrode; and a third electrode contacted to a third portion of the semiconductor layer on other side of the first electrode.

In accordance with some embodiments of the transistor of the first aspect, the semiconductor layer includes: a first channel area disposed between the first electrode and the second electrode; and a second channel area disposed between the first electrode and the third electrode.

In accordance with some embodiments of the transistor of the first aspect, the first electrode transmits the same first signal to the first channel area and the second channel area.

In accordance with some embodiments of the transistor of the first aspect, the transistor further comprises: a first electrode and a fourth electrode disposed on and contacting the first portion of the semiconductor layer; a second electrode electrically connected to a second portion of the semiconductor layer on one side of the first electrode; and a third electrode electrically connected to a third portion of the semiconductor layer on other side of the fourth electrode.

In accordance with some embodiments of the transistor of the first aspect, the first electrode and the fourth electrode are spaced apart from each other by a spacing interposed therebetween, wherein the spacing exposes a portion of an upper surface of the first area of the first insulating layer.

In accordance with some embodiments of the transistor of the first aspect, the semiconductor layer includes: a first channel area disposed between the first electrode and the second electrode; and a second channel area disposed between the fourth electrode and the third electrode.

In accordance with some embodiments of the transistor of the first aspect, the first electrode transmits a first signal to the first channel area, wherein the fourth electrode transmits a second signal different from the first signal to the second channel area.

A second aspect of the present disclosure provides a display apparatus comprising: a light-emitting element; and a transistor connected to the light-emitting element, wherein the transistor includes a substrate; a gate electrode disposed on the substrate; a first insulating layer disposed on the gate electrode; and a semiconductor layer disposed on the first insulating layer so as to overlap the gate electrode in a vertical direction, wherein an upper surface of the first insulating layer includes at least one step, wherein the semiconductor layer is disposed on the upper surface of the first insulating layer having the at least one step in a conformal manner.

In accordance with some embodiments of the display apparatus of the second aspect, the light-emitting element includes: an anode electrode connected to the transistor; a light-emitting layer disposed on the anode electrode; and a cathode electrode disposed on the light-emitting layer.

Although some embodiments of the present disclosure have been described above with reference to the accompanying drawings, the present disclosure may not be limited to some embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some embodiments as described above are not restrictive but illustrative in all respects.

What is claimed is:

1. A transistor comprising:
a substrate;
a gate electrode disposed on the substrate;
a first insulating layer disposed on the gate electrode; and
a semiconductor layer disposed on the first insulating layer so as to overlap the gate electrode in a specific direction,
wherein an upper surface of the first insulating layer includes at least one step.

2. The transistor of claim 1, wherein the semiconductor layer is disposed on the upper surface of the first insulating layer in a conformal manner.

3. The transistor of claim 1, wherein the first insulating layer includes a first area, a second area, and a third area having different thicknesses,
wherein the first area of the first insulating layer has a first thickness based on the gate electrode,
wherein each of the second area and the third area of the first insulating layer has a second thickness different from the first thickness based on the gate electrode.

4. The transistor of claim 3, wherein the first thickness is larger than the second thickness, and the second thickness of the second area and the second thickness of the third area are equal or different from each other.

5. The transistor of claim 3, wherein the first insulating layer includes:
a first inclined surface connecting an upper surface of the first area and an upper surface of the second area of the first insulating layer to each other: and
a second inclined surface connecting an upper surface of the first area and an upper surface of the third area of the first insulating layer to each other.

6. The transistor of claim 5, wherein the semiconductor layer is disposed on the first area of the first insulating layer, the first inclined surface, the second inclined surface, a portion of the second area, and a portion of the third area.

7. The transistor of claim 6, wherein the semiconductor layer includes:
a first portion disposed on the first area of the first insulating layer;
a second portion disposed on the portion of the second area;
a third portion disposed on the portion of the third area;
a first inclined portion disposed on the first inclined surface; and
a second inclined portion disposed on the second inclined surface,
wherein a vertical level of the first portion is higher than a vertical level of each of the second portion and the third portion.

8. The transistor of claim 1, wherein the semiconductor layer includes an oxide semiconductor.

9. The transistor of claim 7, wherein the transistor further comprises:
a first electrode disposed on and contacting the first portion of the semiconductor layer;
a second electrode contacting a second portion of the semiconductor layer on one side of the first electrode; and
a third electrode contacting a third portion of the semiconductor layer on another side of the first electrode.

10. The transistor of claim 9, wherein the semiconductor layer includes:
a first channel area disposed between the first electrode and the second electrode; and
a second channel area disposed between the first electrode and the third electrode.

11. The transistor of claim 10, wherein the first electrode transmits a same first signal to the first channel area and the second channel area.

12. The transistor of claim 7, wherein the transistor further comprises:
a first electrode and a fourth electrode disposed on and contacting the first portion of the semiconductor layer;
a second electrode electrically connected to a second portion of the semiconductor layer on one side of the first electrode; and
a third electrode electrically connected to a third portion of the semiconductor layer on another side of the fourth electrode.

13. The transistor of claim 12, wherein the first electrode and the fourth electrode are spaced apart from each other by a spacing interposed therebetween, and
wherein the spacing exposes a portion of an upper surface of the first area of the first insulating layer.

14. The transistor of claim 12, wherein the semiconductor layer includes:
a first channel area disposed between the first electrode and the second electrode; and
a second channel area disposed between the fourth electrode and the third electrode.

15. The transistor of claim 14, wherein the first electrode transmits a first signal to the first channel area, and
wherein the fourth electrode transmits a second signal different from the first signal to the second channel area.

16. The transistor of claim 1, wherein the specific direction is a vertical direction.

17. A display apparatus comprising:
a light-emitting element; and
a transistor part connected to the light-emitting element,
wherein the transistor part includes the transistor according to claim 1.

18. The display apparatus of claim 17, wherein the light-emitting element includes:
an anode electrode connected to the transistor;
a light-emitting layer disposed on the anode electrode; and
a cathode electrode disposed on the light-emitting layer.
